(19) United States
(12) Patent Application Publication
(10) Pub. No.: US 2016/0031707 A1
(43) Pub. Date: Feb. 4, 2016

(54) MICROELECTRONIC DEVICES AND METHODS FOR MANUFACTURING MICROELECTRONIC DEVICES

(71) Applicant: Micron Technology, Inc.

(72) Inventors: Jonathon G. Greenwood, Boise, ID (US); Derek Gochnour, Boise, ID (US)

(21) Appl. No.: 14/860,419

(22) Filed: Sep. 21, 2015

Related U.S. Application Data
(62) Division of application No. 11/217,886, filed on Sep. 1, 2005, now abandoned.

(51) Int. Cl. B81B 7/00

(52) U.S. Cl. CPC B81B 7/0074; B81B 2207/11

(57) ABSTRACT

Microelectronic devices and methods for manufacturing microelectronic devices are disclosed herein. In one embodiment, a method for manufacturing microelectronic devices includes forming a stand-off layer over a plurality of microelectronic dies on a microfeature workpiece, removing selected portions of the stand-off layer to form a plurality of stand-offs on corresponding dies, cutting the workpiece to singulate the dies, attaching a first singulated die to a support member, and coupling a second die to the stand-off on the first singulated die.

### TECHNICAL FIELD

The present invention is related to microelectronic devices and methods for manufacturing microelectronic devices.

### BACKGROUND

Microelectronic devices generally have a die (i.e., a chip) that includes integrated circuitry having a high density of very small components. In a typical process, a large number of dies are manufactured on a single wafer using many different processes that may be repeated at various stages (e.g., implanting, doping, photolithography, chemical vapor deposition, plasma vapor deposition, plating, planarizing, etching, etc.). The dies typically include an array of very small bond-pads electrically coupled to the integrated circuitry. The bond-pads are the external electrical contacts on the die through which the supply voltage, signals, etc., are transmitted to and from the integrated circuitry. The dies are then separated from one another (i.e., singulated) by dicing the wafer and backgrinding the individual dies. After the dies have been singulated, they are typically “packaged” to couple the bond-pads to a larger array of electrical terminals that can be more easily coupled to the various power supply lines, signal lines, and ground lines.

Conventional processes for packaging dies include electrically coupling the bond-pads on the dies to an array of pins, ball-pads, or other types of electrical terminals, and then encapsulating the dies to protect them from environmental factors (e.g., moisture, particulates, static electricity, and physical impact). In one application, the bond-pads are electrically connected to contacts on an interposer substrate that has an array of ball-pads. For example, FIG. 1A schematically illustrates a conventional packaged microelectronic device 6 including a microelectronic die. 10, an interposer substrate 60 attached to the die 10, a plurality of wire-bonds 90 electrically coupling the die 10 to the interposer substrate 60, and a casing 70 protecting the die 10 from environmental factors.

Electronic products require packaged microelectronic devices to have an extremely high density of components in a very limited space. For example, the space available for memory devices, processors, displays, and other microelectronic components is quite limited in cell phones, PDAs, portable computers, and many other products. As such, there is a strong drive to reduce the surface area or “footprint” of the microelectronic device 6 on a printed circuit board. Reducing the size of the microelectronic device 6 is difficult because high performance microelectronic dies 10 generally have more bond-pads, which result in larger ball-grid arrays and thus larger footprints. One technique used to increase the density of microelectronic dies 10 within a given footprint is to stack one microelectronic die on top of another.

FIG. 1B schematically illustrates another conventional packaged microelectronic device 6a having two stacked microelectronic dies 10a-b. The microelectronic device 6a includes a substrate 60a, a first microelectronic die 10a attached to the substrate 60a, a spacer 30 attached to the first die 10a with a first adhesive 22a, and a second microelectronic die 10b attached to the spacer 30 with a second adhesive 22b. The spacer 30 is a precut section of a semiconductor wafer. One drawback of the packaged microelectronic device 6a illustrated in FIG. 1B is that it is expensive to cut up a semiconductor wafer to form the spacer 30. Moreover, attaching the spacer 30 to the first and second microelectronic dies 10a-b requires additional equipment and steps in the packaging process.

To address these concerns, some conventional packaged microelectronic devices include an epoxy spacer, rather than a section of a semiconductor wafer, to space apart the first and second microelectronic dies 10a and 10b. The epoxy spacer is formed by dispensing a discrete volume of epoxy onto the first die 10a and then pressing the second die 10b downward into the epoxy. One drawback of this method is that it is difficult to position the second die 10b parallel to the first die 10a. As a result, microelectronic devices formed with this method often have “die tilt” in which the distance between the first and second dies varies across the device. If the second die 10b is not parallel to the first die 10a, but rather includes a “high side,” the wire-bonds on the high side may be exposed after encapsulation. Accordingly, there is a need to improve the process of packaging multiple dies in a single microelectronic device.

### BRIEF DESCRIPTION OF THE DRAWINGS

FIG. 1A schematically illustrates a conventional packaged microelectronic device in accordance with the prior art.

FIG. 1B schematically illustrates another conventional packaged microelectronic device in accordance with the prior art.

FIGS. 2-6 illustrate stages in one embodiment of a method for manufacturing a plurality of microelectronic devices.

FIG. 2 is a schematic side cross-sectional view of a portion of a microfeature workpiece.

FIG. 3A is a schematic side cross-sectional view of the portion of the workpiece illustrated in FIG. 2 after forming a plurality of discrete stand-offs on corresponding dies.

FIG. 3B is a schematic top plan view of the portion of the workpiece showing the location of the cross-section illustrated in FIG. 3A.

FIG. 4 is a schematic side cross-sectional view of an assembly including a plurality of singulated microelectronic dies arranged in an array on a support member.

FIG. 5 is a schematic side cross-sectional view of the assembly after attaching a plurality of second microelectronic dies to corresponding stand-offs.

FIG. 6 is a schematic side cross-sectional view of the assembly after forming a casing and attaching a plurality of electrical couplers.

FIGS. 7A-8 illustrate stages in another embodiment of a method for manufacturing a plurality of microelectronic devices.

FIG. 7A is a schematic side cross-sectional view of a microelectronic workpiece.

FIG. 7B is a schematic top plan view of the portion of the workpiece showing the location of the cross-section illustrated in FIG. 7A.

FIG. 8 is a schematic side cross-sectional view of an assembly after attaching the singulated first dies to a support member.

FIG. 9 is a schematic top plan view of a microfeature workpiece in accordance with another embodiment of the invention.

FIGS. 10 and 11 illustrate stages in another embodiment of a method for manufacturing a plurality of microelectronic devices.

FIG. 10 is a schematic side cross-sectional view of a microfeature workpiece.

FIG. 11 is a schematic side cross-sectional view of an assembly including a plurality of singulated microelectronic dies arranged in an array on an interposer substrate.

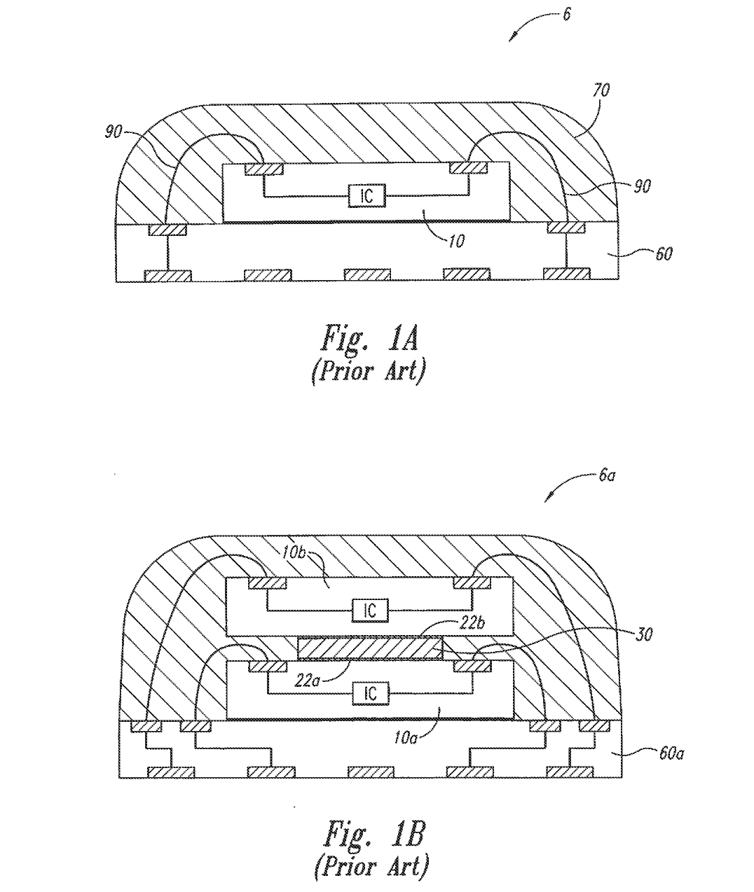

### DETAILED DESCRIPTION

### A. Overview

The following disclosure describes several embodiments of microelectronic devices and methods for manufacturing microelectronic devices. An embodiment of one such method includes forming a stand-off layer over a plurality of microelectronic dies on a microfeature workpiece, removing selected portions of the stand-off layer to form a plurality of stand-offs on corresponding dies, cutting the workpiece to singulate the dies, attaching a first singulated die to a support member, and coupling a second die to the stand-off on the first singulated die. The stand-off layer can be formed on the workpiece by spinning or otherwise depositing a photoactive material onto the workpiece. The stand-offs can be constructed by irradiating portions of the photoactive material and developing the photoactive material.

In another embodiment, a method includes forming a stand-off on a first microelectronic die, coupling the first microelectronic die to a support member after forming the stand-off on the first die, attaching a second microelectronic die to the stand-off on the first die, and encapsulating the first and second dies and at least a portion of the support member. The first die may include an active side, and the stand-off can be formed on the active side. Moreover, the method can further include depositing an adhesive paste onto the first die before attaching the second die to the stand-off.

In another embodiment, a method includes (a) providing a microelectronic die having an active side, a plurality of terminals on the active side, and an integrated circuit electrically coupled to the terminals, (b) forming a stand-off on the active side of the die with at least a portion of the stand-off outboard the terminals, and (c) coupling the die to a substrate with the active side of the die facing the substrate. The method can further include forming a plurality of conductive interconnect elements on corresponding terminals such that interconnect elements electrically connect the die to the substrate.

Another aspect of the invention is directed to microelectronic devices. In one embodiment, a microelectronic device includes a support member and a first microelectronic die attached to the support member. The first die has a backside facing the support member, an active side opposite the backside, a plurality of terminals on the active side, and an integrated circuit electrically coupled to the terminals. The device further includes a plurality of stand-offs on the active side of the first die and a second microelectronic die attached to the stand-offs.

In another embodiment, a microelectronic device includes (a) a substrate, (b) a microelectronic die having an active side attached to the substrate, a plurality of terminals on the active side, and an integrated circuit electrically coupled to the terminals, and (c) a dielectric stand-off on the active side of the die and projecting toward the substrate. The dielectric stand-off is positioned so that at least a portion is outboard the terminals.

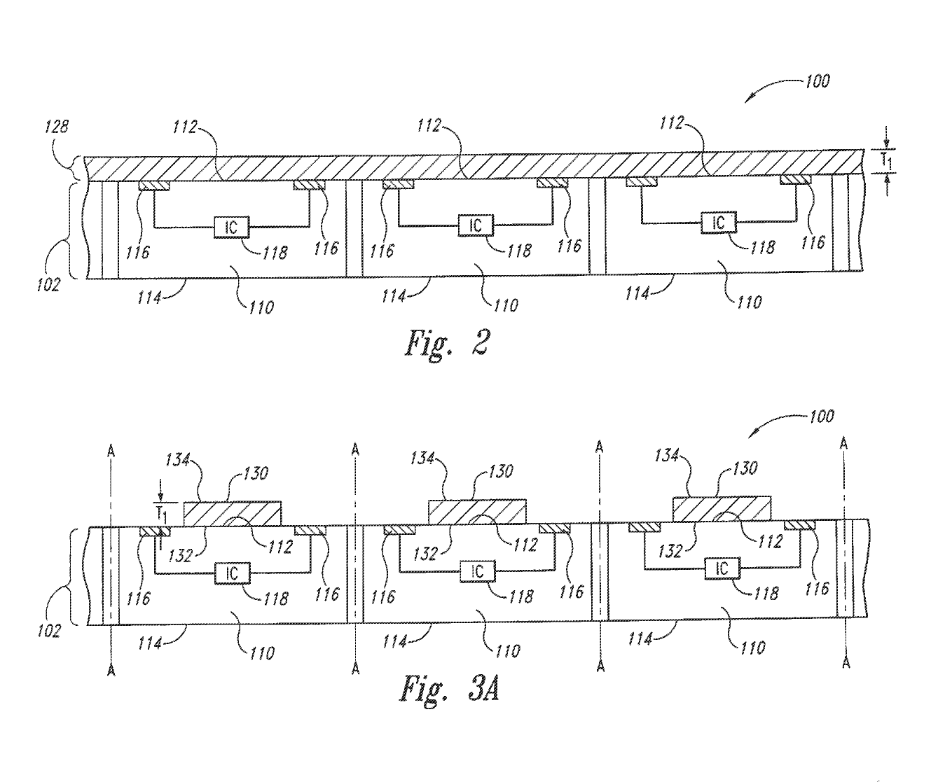

Specific details of several embodiments of the invention are described below with reference to microelectronic devices with two stacked microelectronic dies, but in other embodiments the microelectronic devices can have a different number of stacked dies. Several details describing well-known structures or processes often associated with fabricating microelectronic dies and microelectronic devices are not set forth in the following description for purposes of clarity. Also, several other embodiments of the invention can have different configurations, components, or procedures than those described in this section. A person of ordinary skill in the art, therefore, will accordingly understand that the invention may have other embodiments with additional elements, or the invention may have other embodiments without several of the elements shown and described below with reference to FIGS. 2-11.

The term “microfeature workpiece” is used throughout to include substrates upon which and/or in which microelectronic devices, micromechanical devices, data storage elements, optics, and other features are fabricated. For example, microfeature workpieces can be semiconductor wafers, glass substrates, dielectric substrates, or many other types of substrates. Many features on such microfeature workpieces have critical dimensions less than or equal to 1 μm, and in many applications the critical dimensions of the smaller features are less than 0.25 μm or even less than 0.1 μm. Where the context permits, singular or plural terms may also include the plural or singular term, respectively. Moreover, unless the word “or” is expressly limited to mean only a single item exclusive from other items in reference to a list of at least two items, then the use of “or” in such a list is to be interpreted as including (a) any single item in the list, (b) all of the items in the list, or (c) any combination of the items in the list. Additionally, the term “comprising” is used throughout to mean including at least the recited feature(s) such that any greater number of the same features and/or types of other features and components are not precluded.

### B. Embodiments of Methods for Manufacturing Microelectronic Devices

FIGS. 2-6 illustrate stages in one embodiment of a method for manufacturing a plurality of microelectronic devices. For example, Figure. 2 is a schematic side cross-sectional view of a portion of a microfeature workpiece 100 including a substrate 102 and a plurality of microelectronic dies 110 (only three are shown) formed in and/or on the substrate 102. The individual dies 110 include an active side 112, a backside 114 opposite the active side 112, a plurality of terminals 116 (e.g., bond-pads) arranged in an array on the active side 112, and an integrated circuit 118 (shown schematically) operably coupled to the terminals 116. Although the illustrated dies 110 have the same structure, in other embodiments the dies may have different features to perform different functions.

After constructing the microelectronic dies 110, a stand-off layer 128 is formed across the microfeature workpiece 100. The stand-off layer 128 can be formed on the workpiece 100 by spin-on, film lamination, or other suitable processes. The stand-off layer 128 has a precise thickness T₁, which corresponds to the desired distance between pairs of stacked microelectronic dies in a microelectronic device as described in greater detail below. For example, in several embodiments, the thickness T₁ of the stand-off layer 128 can be approximately 75 microns. The stand-off layer 128 may be composed of epoxy, epoxy acrylic, polyimide, or other suitable photoactive materials capable of being photo-defined.

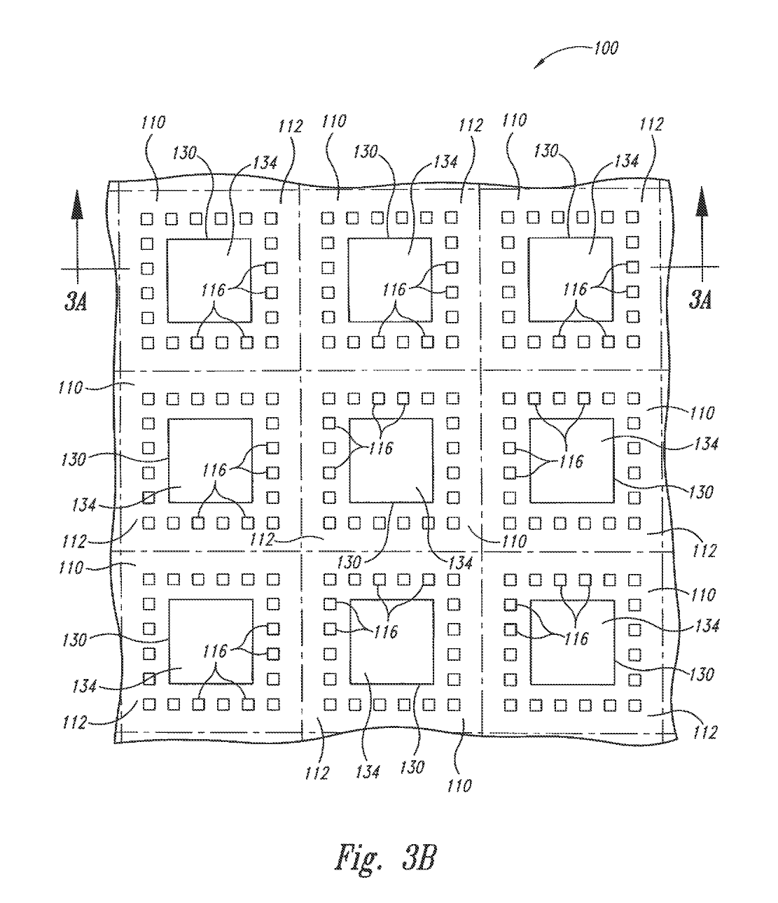

FIG. 3A is a schematic side cross-sectional view of the portion of the microfeature workpiece 100 after forming a plurality of discrete stand-offs 130 on corresponding dies 110. FIG. 3B is a schematic top plan view of the portion of the workpiece 100 showing the location of the cross-section illustrated in FIG. 3A. Referring to both FIGS. 3A and 3B, after forming the stand-off layer 128 (FIG. 2) on the workpiece 100, the layer 128 is patterned and developed to construct the discrete stand-offs 130. The individual stand-offs 130 include a first surface 132 (FIG. 3A) attached to the active side 112 of the dies 110 and a second surface 134 opposite the first surface 132. The first surfaces 132 are attached to the dies 110 without an adhesive because the stand-offs 130 themselves adhere to the dies 110. The second surfaces 134 are generally planar and oriented parallel to the active sides 112 of the dies 110. The illustrated stand-offs 130 are positioned inboard the terminals 116 and over the central portion of the corresponding dies 110. Although in the illustrated embodiment the stand-offs 130 have a rectangular cross-sectional shape and are positioned on the dies 110 in a one-to-one correspondence, in other embodiments the stand-offs can have other cross-sectional shapes and/or a plurality of stand-offs can be formed on each die 110. In any of these embodiments, after forming the stand-offs 130 on the dies 110, the workpiece 100 can be cut along lines A-A (FIG. 3A) to singulate the individual dies 110.

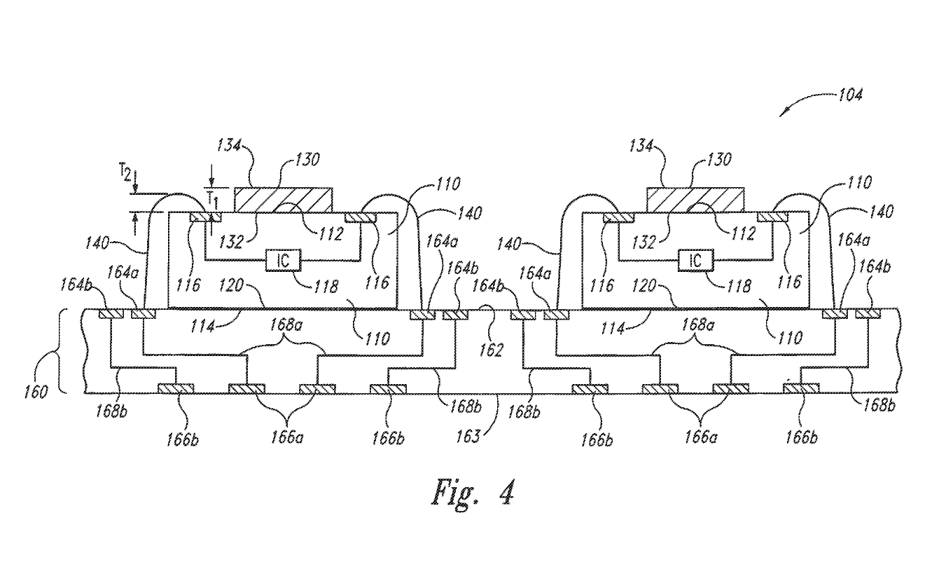

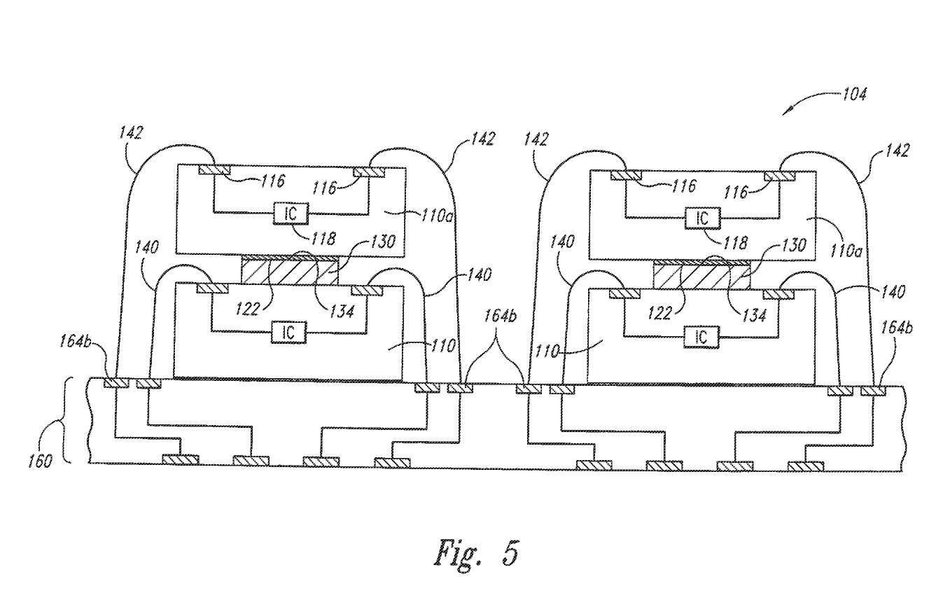

FIG. 4 is a schematic side cross-sectional view of an assembly 104 including the singulated microelectronic dies 110 (only two are shown) arranged in an array on a support member 160. The individual singulated dies 110 are attached to the support member 160 with an adhesive 120 such as an adhesive film, epoxy, or other suitable material. The support member 160 can be a lead frame or a substrate, such as a printed circuit board, for carrying the microelectronic dies 110. The illustrated support member 160 includes a first side 162 attached to the backside 114 of the dies 110 and a second side 163 opposite the first side 162. The first side 162 includes (a) a plurality of first contacts 164a arranged in arrays for attachment to corresponding terminals 116 on the dies 110, and (b) a plurality of second contacts 164b arranged in arrays for attachment to corresponding terminals on a plurality of second dies (shown in FIG. 5). The second side 163 includes (a) a plurality of first pads 166a electrically connected to corresponding first contacts 164a with a plurality of first conductive traces 168a, and (b) a plurality of second pads 166b electrically connected to corresponding second contacts 164b with a plurality of second conductive traces 168b. The first and second pads 166a-b are arranged in arrays to receive corresponding electrical couplers (e.g., solder balls).

The illustrated assembly 104 further includes a plurality of first wire-bonds 140 electrically coupling the terminals 116 on the dies 110 to corresponding first contacts 164a on the support member 160. The individual first wire-bonds 140 project a distance T₂ from the active side 112 of the dies 110 that is less than the height T₁ of the stand-offs 130. As a result, a plurality of second microelectronic dies can be attached to the second surface 134 of the stand-offs 130 without contacting the first wire-bonds 140. For purposes of clarity and brevity, the microelectronic dies 110 described above with reference to FIGS. 2-4 shall hereinafter be referred to as the first microelectronic dies 110.

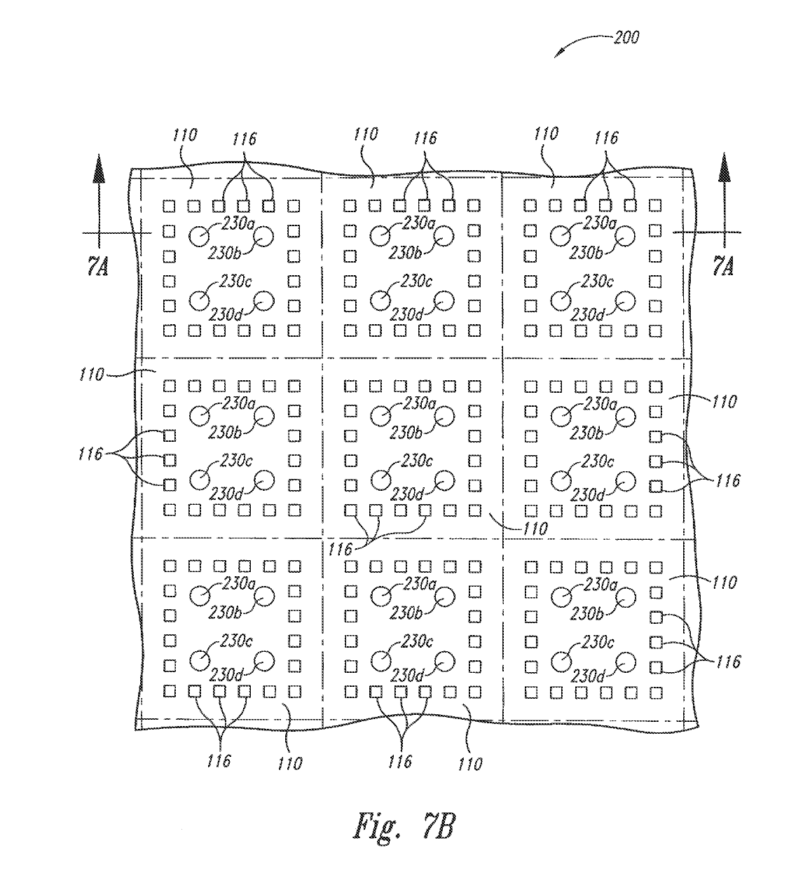

FIG. 5 is a schematic side cross-sectional view of the assembly 104 after attaching a plurality of second microelectronic dies 110a to corresponding stand-offs 130. The second microelectronic dies 110a can either be generally similar to the first dies 110 or have different features to perform different functions. The second dies 110a are attached to the second surface 134 of the stand-offs 130 with an adhesive 122. The adhesive 122 can be a wafer backside adhesive (WBA) that is applied to the second dies 110a before the second dies 110a are attached to the stand-offs 130, or the adhesive 122 can be another suitable adhesive material. Although the second dies 110a have generally the same footprint as the first dies 110, in other embodiments, such as the embodiment described below with reference to FIG. 8, the second dies can have a footprint greater than or less than the footprint of the first dies. In either case, after attaching the second dies 110a to the stand-offs 130, the assembly 104 can optionally be heated to cure the adhesive 122 and/or the stand-offs 130. Next, the terminals 116 on the second dies 110a can be electrically coupled to corresponding second contacts 164b on the support member 160 with a plurality of second wire-bonds 142. In other embodiments, the assembly 104 may also include a plurality of stand-offs formed on the active sides of the second dies 110a and/or additional dies stacked on top of the second dies 110a.

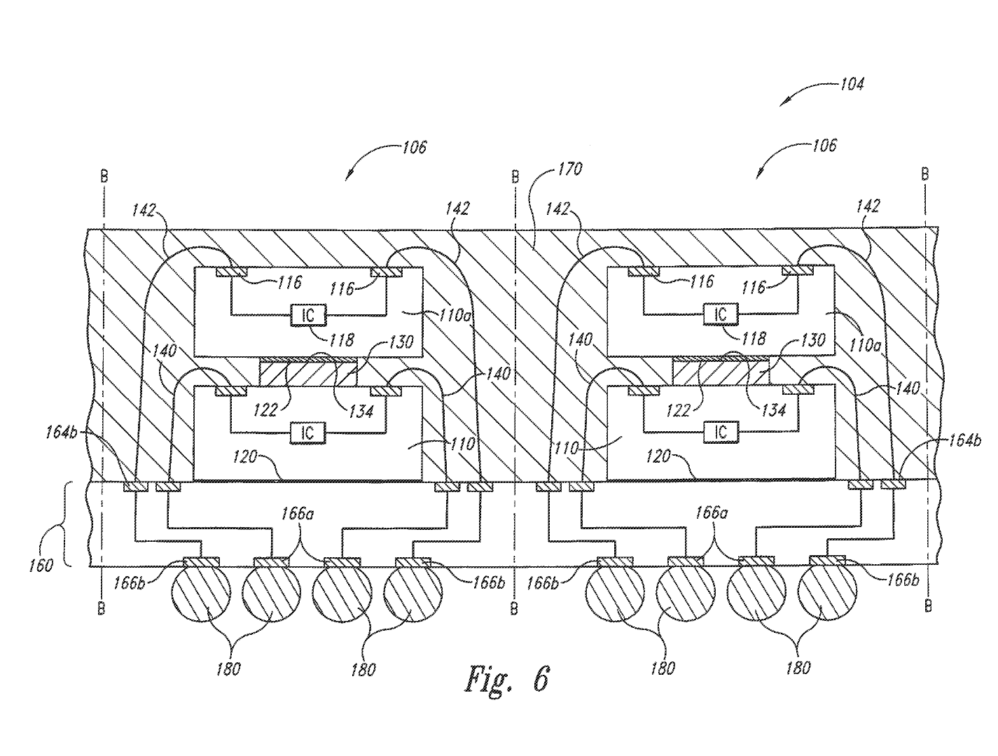

FIG. 6 is a schematic side cross-sectional view of the assembly 104 after forming a casing 170 and attaching a plurality of electrical couplers 180. The casing 170 encapsulates the first and second microelectronic dies 110 and 110a, the first and second wire-bonds 140 and 142, and a portion of the support member 160. The casing 170 can be formed by conventional injection molding, fill molding, or other suitable processes. After forming the casing 170, the electrical couplers 180 can be attached to corresponding pads 166a-b on the support member 160, and the assembly 104 can be cut along lines B-B to singulate a plurality of individual microelectronic devices 106.

One advantage of the method for manufacturing the microelectronic devices 106 illustrated in FIGS. 2-6 is that the method is expected to significantly enhance the efficiency of the manufacturing process because a plurality of microelectronic devices 106 can be fabricated simultaneously using highly accurate and efficient processes developed for packaging and manufacturing semiconductor devices. This method of manufacturing microelectronic devices 106 is also expected to enhance the quality and performance of the microelectronic devices 106 because the semiconductor fabrication processes can reliably produce and assemble the various components with a high degree of precision. For example, the stand-offs 130 can be formed with a precise, uniform thickness T₁ and have a planar second surface 134 so that the second microelectronic dies 110a are oriented generally parallel to the corresponding first microelectronic dies 110. As a result, the microelectronic devices 106 are not expected to have problems with die tilt and the concomitant exposure of wire-bonds. Moreover, the stand-offs 130 can be formed with relatively inexpensive materials, rather than expensive sections of a semiconductor wafer.

### C. Additional Embodiments of Methods for Manufacturing Microelectronic Devices

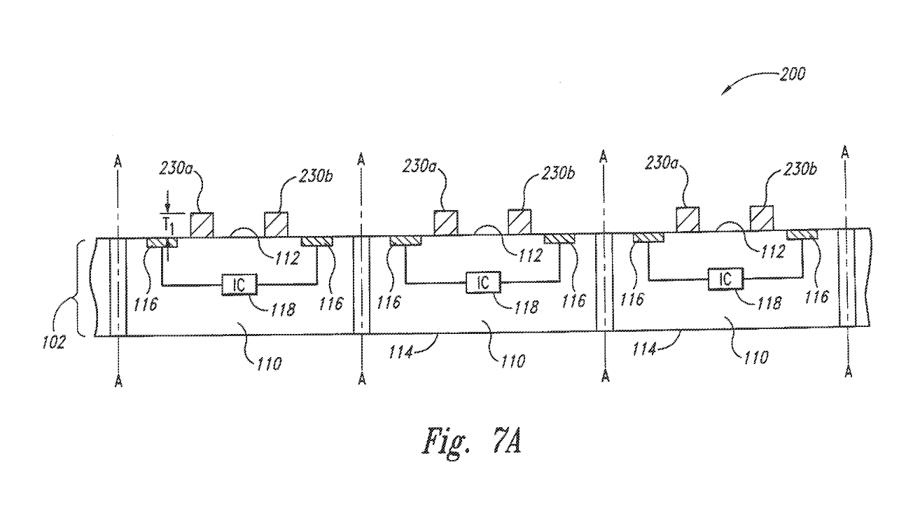

FIGS. 7A-8 illustrate stages in another embodiment of a method for manufacturing a plurality of microelectronic devices. For example, FIG. 7A is a schematic side cross-sectional view of a microelectronic workpiece 200 having a substrate 102 and a plurality of first microelectronic dies 110 (only three are shown) formed in and/or on the substrate 102. FIG. 7B is a schematic top plan view of the portion of the workpiece 200 showing the location of the cross-section illustrated in FIG. 7A. Referring to both FIGS. 7A and 7B, the microfeature workpiece 200 is generally similar to the workpiece 100 described above with reference to FIGS. 3A and 3B. The illustrated workpiece 200, however, includes a plurality of stand-offs 230 (identified individually as 230a-d) arranged on the individual first dies 110. The illustrated stand-offs 230 are posts that project a distance T₁ (FIG. 7A) from the active side 112 of the individual first dies 110. Although in the illustrated embodiment, four stand-offs 230 are positioned inboard the terminals 116 on the active side 112 of each first die 110, in other embodiments the stand-offs can have other configurations and/or be arranged in other positions on the dies. In either case, after forming the stand-offs 230, the workpiece 200 can be cut along lines A-A (FIG. 7A) to singulate the individual first dies 110.

FIG. 8 is a schematic side cross-sectional view of an assembly 204 after attaching the singulated first dies 110 to a support member 160 and coupling a plurality of second dies 210 to corresponding first dies 110. The illustrated second dies 210 are attached to the first dies 110 with an adhesive paste 222. The adhesive paste 222 can be deposited onto the active side 112 of the first dies 110 and/or the backside 114 of the second dies 210 before the second dies 210 are placed on a surface 234 of the stand-offs 230. The stand-offs 230 are positioned within the adhesive paste 222 and extend between the backside 114 of the second dies 210 and the active side 112 of the first dies 110 to space the first and second dies 110 and 210 apart by a desired distance T₁. In other embodiments, the second dies 210 can be attached to the first dies 110 without an adhesive paste filling the gap between the first and second dies 110 and 210. For example, an adhesive tape can be attached to the backside 11.4 of the second dies 210 and/or the surface 234 of the stand-offs 230 to adhere the second dies 210 to the stand-offs 230. Moreover, although the footprint of the illustrated second dies 210 is greater than the footprint of the first dies 110, in other embodiments the footprint of the second dies can be less than or generally equal to the footprint of the first dies. In any of these embodiments, after attaching the second dies 210 to corresponding first dies 110, the second dies 210 can be wire-bonded to the support member 160, and the assembly 204 can be encased and cut to singulate the individual microelectronic devices.

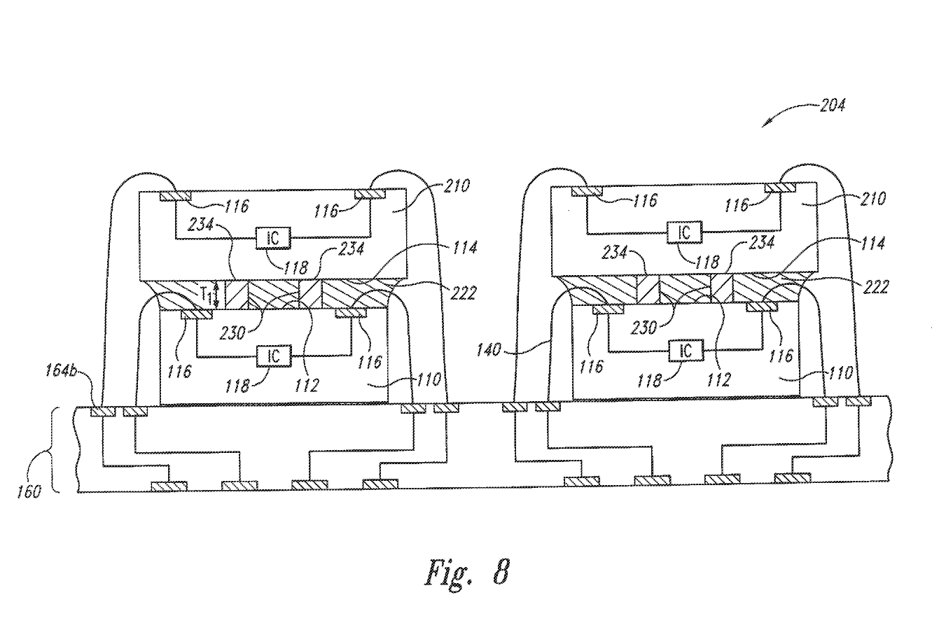

FIG. 9 is a schematic top plan view of a microfeature workpiece 300 in accordance with another embodiment of the invention. The illustrated workpiece 300 includes a substrate 102, a plurality of dies 110 formed in and/or on the substrate 102, and a plurality of stand-offs 330 (identified individually as 330a-c) arranged in arrays on the dies 110. The illustrated stand-off arrays include three stand-offs 330 positioned on the individual dies 110 inboard the terminals 116. The illustrated stand-offs 330 are rectangular posts projecting from the active side 112 of the dies 110 a precise distance corresponding to the desired distance between the stacked first and second dies 110 and 210 (FIG. 8). Although the illustrated workpiece 300 includes arrays of three stand-offs 330 on each die 110, in other embodiments the workpieces can include a different number of stand-offs on each die.

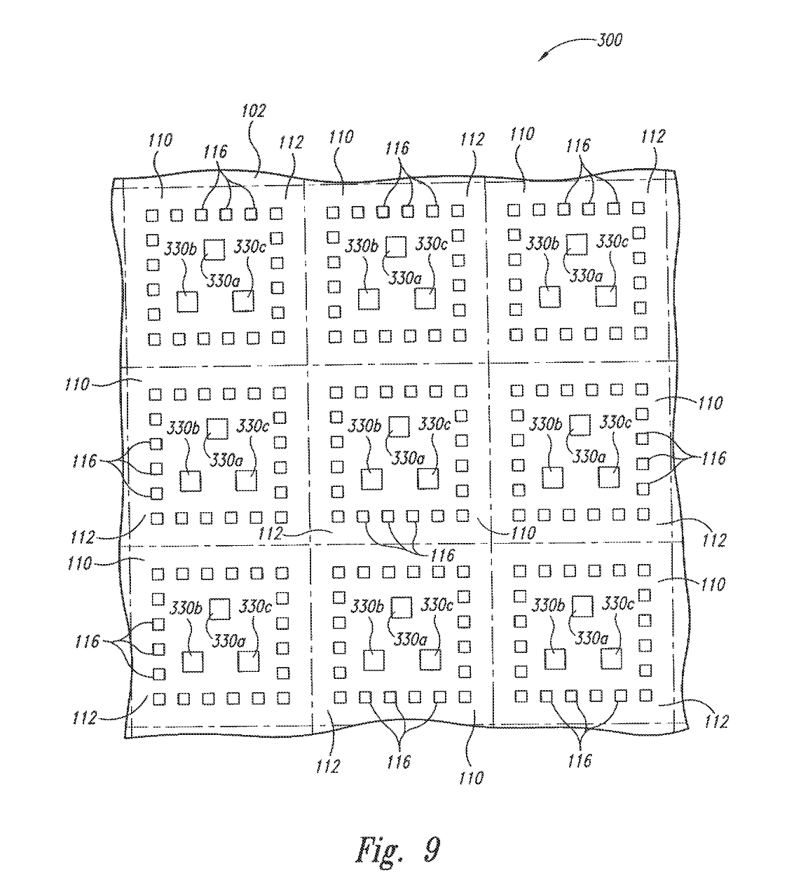

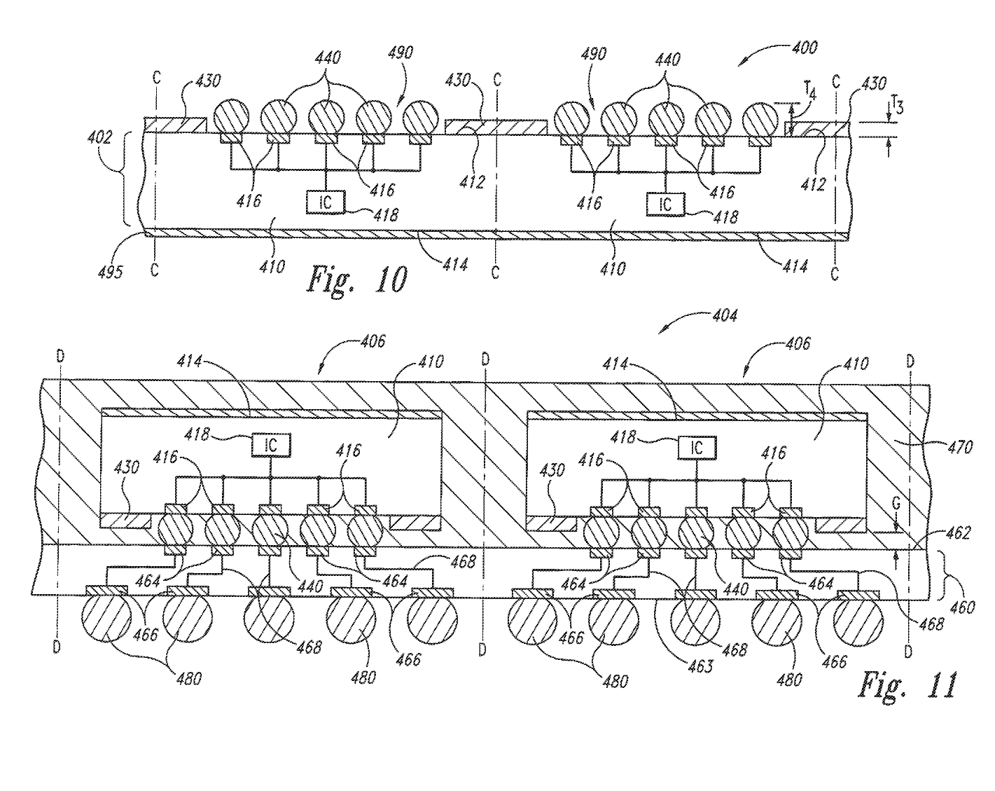

FIGS. 10 and 11 illustrate stages in another embodiment of a method for manufacturing a plurality of microelectronic devices. For example, FIG. 10 is a schematic side cross-sectional view of a microfeature workpiece 400 having a substrate 402 and a plurality of microelectronic dies 410 (only two are shown) formed in and/or on the substrate 402. The individual dies 410 include an active side 412, a backside 414 opposite the active side 412, a plurality of terminals 416 (e.g., bond-pads) arranged in an array on the active side 412, and an integrated circuit 418 (shown schematically) operably coupled to the terminals 416.

After constructing the microelectronic dies 410, a plurality of dielectric stand-offs 430 are formed across the workpiece 400. The dielectric stand-offs 430 can be formed by depositing a stand-off layer across the workpiece 400 and exposing and developing the layer to form a plurality of openings 490 over corresponding dies 410. The individual openings 490 are formed over the central portion of the dies 410 and expose the terminals 416. As such, the stand-offs 430 form dams that project a first distance T₃ from the active side 412 and surround the central portion of the individual dies 410. After forming the stand-offs 430 on the dies 410, a plurality of interconnect elements 440 can be formed on corresponding terminals 416. The interconnect elements 440 can be solder balls or other conductive members that project a second distance T₄ from the active side 412 of the dies 410 that is greater than the first distance T₃. After forming the interconnect elements 440, the workpiece 400 can be cut along lines C-C to singulate the individual dies 410. In several applications, the workpiece 400 may further include a backside protection layer 495 extending across the backside 414 of the dies 410 to protect the dies 410 during singulation and/or other processes.

FIG. 11 is a schematic side cross-sectional view of an assembly 404 including the singulated microelectronic dies 410 arranged in an array on an interposer substrate 460. The illustrated interposer substrate 460 includes (a) a first side 462 having a plurality of contacts 464 arranged in arrays, (b) a second side 463 having a plurality of pads 466 arranged in arrays, and (c) a plurality of conductive traces 468 electrically connecting the contacts 464 to corresponding pads 466. The dies 410 are attached to the interposer substrate 460 with the interconnect elements 440 such that the interconnect elements 440 form a physical and electrical connection between the dies 410 and the substrate 460. When the dies 410 are attached to the interposer substrate 460, the stand-offs 430 are spaced apart from the first side 462 of the substrate 460 by a gap G. After attaching the dies 410 to the substrate 460, a casing 470 is formed over the dies 410, a plurality of electrical couplers 480 can be attached to corresponding pads 466, and the assembly 404 can be cut along lines D-D to singulate the individual microelectronic devices 406.

One advantage of the microelectronic devices 406 illustrated in FIGS. 10 and 11 is that the stand-offs 430 protect the microelectronic dies 410 during burn-in and testing. For example, particles and contaminants from other processes, such as chemical-mechanical planarization, vapor deposition, etc., may be carried to the test sockets on bare dies. This debris can accumulate on the surfaces in the test sockets and eventually scratch, impinge, pierce, contaminate, and/or otherwise damage subsequent bare dies when the dies are placed in the sockets. The stand-offs 430 protect the illustrated microelectronic dies 410 because when the dies 410 are placed in a socket the stand-offs 430 contact the support surface of the socket and space the active side 412 of the dies 410 away from the support surface. Consequently, the debris on the support surfaces of the test sockets cannot puncture the soft, protective coating on the active side 412 of the dies 410 and damage its internal circuitry. The stand-offs 430 also protect the perimeter portion of the dies 410 from chipping or other damage if the dies 410 contact assembly components during different fabrication processes.

From the foregoing, it will be appreciated that specific embodiments of the invention have been described herein for purposes of illustration, but that various modifications may be made without deviating from the spirit and scope of the invention. For example, many of the elements of one embodiment can be combined with other embodiments in addition to or in lieu of the elements of the other embodiments. Accordingly, the invention is not limited except as by the appended claims.

1-33. (canceled)

34. A microelectronic device, comprising:
a support member;
a first microelectronic die including a back side attached to the support member, an active side opposite the back side, a plurality of terminals on the active side, and an integrated circuit electrically coupled to the terminals;
a plurality of stand-offs on the active side of the first microelectronic die; and
a second microelectronic die attached to the stand-offs.

35. The microelectronic device of claim 34 wherein the stand-offs comprise a photoactive material.

36. The microelectronic device of claim 34 wherein the support member comprises a plurality of contacts, and wherein the device further comprises a plurality of wire-bonds extending between the terminals of the first die and corresponding contacts on the support member.

37. The microelectronic device of claim 34 wherein the support member comprises a plurality of first contacts and a plurality of second contacts, wherein the second microelectronic die comprises a plurality of terminals, and wherein the device further comprises (a) a plurality of first wire-bonds extending between the terminals of the first microelectronic die and corresponding first contacts, and (b) a plurality of second wire-bonds extending between the terminals of the second microelectronic die and corresponding second contacts.

38. The microelectronic device of claim 34, further comprising an adhesive paste between the first and second microelectronic dies.

39. The microelectronic device of claim 34, further comprising a casing covering the first and second microelectronic dies and at least a portion of the support member.

40. The microelectronic device of claim 34 wherein the stand-offs are positioned inboard the terminals of the first microelectronic die.

41. The microelectronic device of claim 34 wherein the stand-offs are attached to the first microelectronic die without an adhesive.

42. The microelectronic device of claim 34 wherein the support member comprises an interposer substrate having a plurality of pads, and wherein the device further comprises a plurality of electrical couplers on corresponding pads.

43. The microelectronic device of claim 34 wherein the stand-offs comprise at least three stand-offs.

44. A microelectronic device, comprising:
a support member;
a first microelectronic die including a back side attached to the support member, an active side opposite the back side, a plurality of terminals on the active side, and an integrated circuit electrically coupled to the terminals;
a stand-off attached to the active side of the first microelectronic die without an adhesive between the stand-off and the active side of the first microelectronic die;
a second microelectronic die attached to the stand-off; and
an adhesive attaching the second microelectronic die to the stand-off.

45. The microelectronic device of claim 44 wherein the stand-off comprises a photoactive material.

46. The microelectronic device of claim 44 wherein the support member comprises a plurality of contacts, and wherein the device further comprises a plurality of wire-bonds extending between the terminals of the first die and corresponding contacts on the support member.

47. The microelectronic device of claim 44 wherein the stand-off is a first stand-off, and wherein the device further comprises a second stand-off attached between the first and second microelectronic dies.

48. The microelectronic device of claim 44 wherein the stand-off is a first stand-off, and wherein the device further comprises (a) a second stand-off attached between the first and second microelectronic dies, and (b) an adhesive paste between the first and second microelectronic dies.

49. The microelectronic device of claim 44, further comprising a casing covering the first and second microelectronic dies and at least a portion of the support member.

50. The microelectronic device of claim 44 wherein the stand-off is positioned inboard the terminals of the first microelectronic die.

51. A microelectronic device, comprising:
a substrate;
a microelectronic die including an active side attached to the substrate, a plurality of terminals on the active side, and an integrated circuit electrically coupled to the terminals; and
a dielectric stand-off on the active side of the microelectronic die and projecting toward the substrate, wherein at least a portion of the dielectric stand-off is positioned outboard the terminals.

52. The microelectronic device of claim 51 wherein the substrate comprises a plurality of contacts, and wherein the device further comprises a plurality of interconnect elements electrically coupling the terminals to corresponding contacts.

53. The microelectronic device of claim 51 wherein the dielectric stand-off comprises a photoactive material.

54. The microelectronic device of claim 51 wherein the dielectric stand-off is spaced apart from the substrate by a gap.

55. The microelectronic device of claim 51, further comprising a casing covering the microelectronic die and at least a portion of the substrate.

56. The microelectronic device of claim 51 wherein the substrate comprises an interposer substrate having a plurality of pads, and wherein the device further comprises a plurality of electrical couplers on corresponding pads.

57. The microelectronic device of claim 51 wherein the dielectric stand-off comprises a dam surrounding a perimeter region of the active side of the die.
